(19) United States
(12) Patent Application Publication
(10) Pub. No.: US 2026/0266406 A1
(43) Pub. Date: Sep. 10, 2026

(54) CONNECTOR FOR PRECURSOR DELIVERY

(71) Applicant: LAM RESEARCH CORPORATION, Fremont, CA (US)

(72) Inventors: Saurish DAS, Siliguri (IN); Lav KAUSHIK, Bangalore (IN); Debotosh PODDAR, Durgapur (IN)

(21) Appl. No.: 19/163,718

(22) PCT Filed: Mar. 4, 2024
(86) PCT No.: PCT/US2024/018322

§ 371 Date: Sep. 9, 2025

Related U.S. Application Data
(60) Provisional application No. 63/452,328, filed on Mar. 15, 2023.

(51) Int. Cl. F16L 41/02; H10P 72/00

(52) U.S. Cl. CPC F16L 41/021; H10P 72/0402

(57) ABSTRACT

A connector for a substrate processing system includes a body comprising a first body portion including an inlet and an outlet and defining a first gas flow channel extending in a first direction from the inlet to the outlet. A second body portion includes an inlet and defining a second gas flow channel extending in a second direction that is different than the first direction. A “T”-shaped conduit is arranged in the first gas flow channel and includes a first conduit portion defining a third gas flow channel extending in the second direction and including an inlet connected to the second gas flow channel. A second conduit portion is connected to a downstream side of the first body portion and defining a fourth gas flow channel extending in the first direction and in fluid communication with the third gas flow channel.

### CROSS-REFERENCE TO RELATED APPLICATIONS

This application claims the benefit of U.S. Provisional Application No. 63/452,328, filed on Mar. 15, 2023. The entire disclosure of the application referenced above is incorporated herein by reference.

### FIELD

The present disclosure relates to substrate processing systems, and more particularly to a connector for precursor delivery.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. The substrate treatments may include deposition, etching, cleaning, and/or other substrate treatments. A substrate is arranged on a substrate support such as an electrostatic chuck (ESC) in a processing chamber. During processing, a gas delivery system introduces gas mixtures and/or vapor into the processing chamber using a showerhead, an injector, and/or other gas distribution device.

During atomic layer deposition (ALD) or atomic layer etching (ALE), a substrate is cycled through a process including exposure to a first precursor, a first purge step, exposure to a second precursor, and a second purge step. Since the ALD or ALE process typically deposits or etches a monolayer during each cycle, the ALD or ALE process is repeated relatively quickly.

### SUMMARY

A connector for a substrate processing system includes a body comprising a first body portion including an inlet and an outlet and defining a first gas flow channel extending in a first direction from the inlet to the outlet. A second body portion includes an inlet and defining a second gas flow channel extending in a second direction that is different than the first direction. A “T”-shaped conduit is arranged in the first gas flow channel and includes a first conduit portion defining a third gas flow channel extending in the second direction and including an inlet connected to the second gas flow channel. A second conduit portion is connected to a downstream side of the first body portion and defining a fourth gas flow channel extending in the first direction and in fluid communication with the third gas flow channel.

In other features, the first body portion includes a first slot and a second slot located on an inner surface of the first gas flow channel, wherein opposite sides of the first conduit portion are received in the first slot and the second slot. The second body portion comprises an interlocking portion configured to engage the inlet of the first conduit portion. The interlocking portion of the second body portion comprises a gas conduit including a male projection received in the inlet of the first conduit portion. A plug arranged in the third gas flow channel downstream from a connection to the fourth gas flow channel and including an arcuate surface configured to redirect gas flowing in the third gas flow channel into the fourth gas flow channel.

In other features, an inner diameter of the first gas flow channel is greater than an outer diameter of the first conduit portion and the second conduit portion. An inner diameter of the first gas flow channel is at least 1.5 times greater than an outer diameter of the first conduit portion and the second conduit portion. The first direction is transverse to the second direction.

A connector for a substrate processing system includes a body comprising a first body portion including an inlet and an outlet and defining a first gas flow channel extending in a first direction between the inlet and the outlet and a second body portion including an inlet and defining a second gas flow channel extending in a second direction that is different than the first direction. A gas conduit is arranged in the first gas flow channel and defines a third gas flow channel extending in the second direction. The gas conduit includes an inlet connected to the second gas flow channel and a plurality of gas through holes passing through the gas conduit on a downstream side of the gas conduit.

In other features, the first body portion includes a first slot and a second slot located in the first gas flow channel and configured to receive opposite sides of the gas conduit. The second body portion comprises an interlocking portion configured to engage the inlet of the gas conduit. The interlocking portion of the second body portion comprises a gas conduit including a male projection received in the inlet of the gas conduit. A plug is arranged in gas conduit downstream from the plurality of gas through holes.

In other features, an inner diameter of the first gas flow channel is greater than an outer diameter of the gas conduit. An inner diameter of the first gas flow channel is at least 1.5 times greater than an outer diameter of the gas conduit. The plurality of gas through holes are configured to provide a conical gas flow pattern. The first direction is transverse to the second direction.

A connector for a substrate processing system includes a body comprising a first body portion including an inlet and an outlet and defining a first gas flow channel extending in a first direction from the inlet to the outlet and a second body portion including an inlet and an outlet and defining a second gas flow channel extending in a second direction that is different than the first direction. A cantilevered body portion extends from the second body portion into the first gas flow channel and includes an angled body portion extending from the second body portion into the first gas flow channel. A third body portion extends from the angled body portion in the first gas flow channel. The second gas flow channel extends through the second body portion, the angled body portion and the first body portion. Gas flowing through the first gas flow channel is combined with gas flowing through the second gas flow channel at the outlet of the third body portion.

In other features, the connector is made using additive manufacturing. An inner diameter of the first gas flow channel is greater than an outer diameter of the angled body portion and the third body portion of the cantilevered body portion. An inner diameter of the first gas flow channel is greater than 1.5 times an outer diameter of the angled body portion and the third body portion of the cantilevered body portion. The first direction is transverse to the second direction. A cavity is defined in the second body portion around the second gas flow channel. A heater is arranged in the cavity.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of a substrate processing system including a gas delivery system including a “T”-shaped connector according to the present disclosure;

FIG. 2 is a flowchart of a method for performing atomic layer deposition according to the present disclosure;

FIGS. 3A to 3C are functional block diagrams illustrating gas flow during ALD according to the present disclosure;

FIG. 4A is a side cross-sectional view of a “T”-shaped connector according to the present disclosure;

FIG. 4B is a partial top view illustrating the “T”-shaped connector according to the present disclosure;

FIGS. 5A and 5B are perspective views of the “T”-shaped connector according to the present disclosure;

FIG. 6A is a side cross-sectional view of another “T”-shaped connector according to the present disclosure;

FIG. 6B is a bottom view illustrating a hole pattern according to the present disclosure;

FIG. 6C is a perspective view illustrating a gas jet pattern for the hole pattern of FIG. 6B;

FIG. 7A is a side cross-sectional view of another “T”-shaped connector according to the present disclosure; and

FIG. 7B is a top view of the “T”-shaped connector of FIG. 7A.

In the drawings, reference numbers may be reused to identify similar and/or identical elements.

### DETAILED DESCRIPTION

While the “T”-shaped connector is described below in the context of an atomic layer deposition (ALD) process, the “T”-shaped connector according to the present disclosure can be used for atomic layer etching (ALE), chemical vapor deposition (CVD), plasma enhanced layer deposition, or other types of substrate treatments.

In some applications, different gas or vapor mixtures are supplied by different gas flow paths that are mixed at a connector such as a “T”-shaped connector before delivery to a processing chamber. As can be appreciated, ineffective mixing of gases and/or vapor that are delivered to the processing chamber by the T″-shaped connector during substrate processing may adversely affect substrate nonuniformity (NU). For example, ineffective mixing of the carrier gas and the precursor during a dose step during atomic layer deposition (ALD) may cause variations in deposition thickness of film at different locations of the substrate.

To improve mixing of gases after the “T”-shaped connector, a helical mixer may be used. The helical mixer is arranged inside of a gas conduit and includes helical-shaped portions extending into the gas flow channel to cause helical mixing of the gases flowing therethrough. While helical mixers in the gas conduit increase mixing of the gases supplied by the “T”-shaped connector, the helical mixers cause an unacceptable pressure drop and/or backflow of the purge gas and/or the second precursor during a burst purge step. Helical mixers may also increase substrate defects by introducing undesired particles and/or powder.

The “T”-shaped connector according to the present disclosure improves mixing, reduces NU without causing high pressure drops and/or back flow, and reduces particle formation in the conduit. In some examples, the pressure drop of the “T”-shaped connectors described below during a burst purge is reduced by 50% or more.

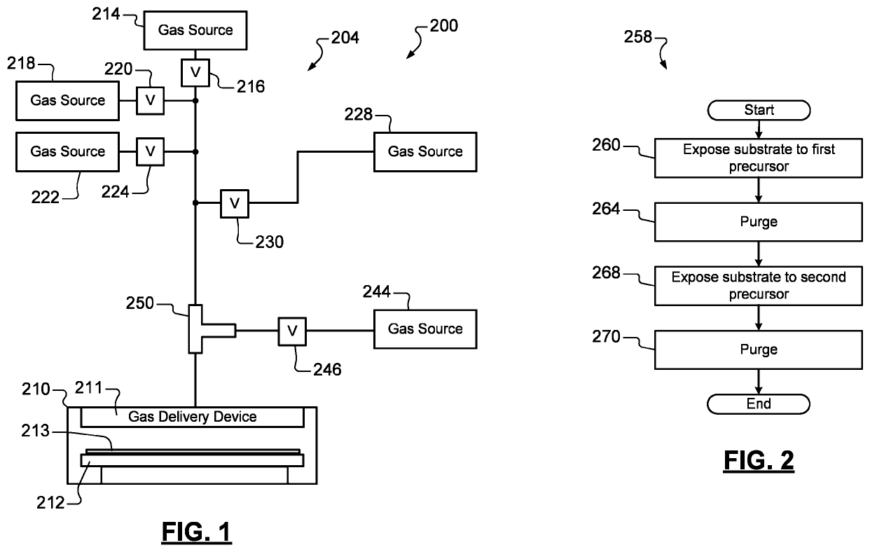

Referring now to FIG. 1, a substrate processing system 200 includes a processing chamber 210 including a gas distribution device 211 such as a showerhead, an injector or other gas distribution device. A substrate support 212 such as an electrostatic chuck or a pedestal is arranged in the processing chamber 210. A substrate 213 is delivered by a robot to the processing chamber 210, processed, and then removed by the robot from the processing chamber 210.

A gas delivery system 204 includes a “T”-shaped connector 250. Gas sources are connected to the “T”-shaped connector 250. Gas source 214 is selectively fluidly connected by a valve 216 to a first inlet of the “T”-shaped connector 250. Likewise, gas sources 218, 222, and 228 are selectively fluidly connected by valves 220, 224, and 230 to the first inlet of the “T”-shaped connector 250. A gas source 244 is selectively fluidly connected by a valve 246 to a second inlet of the “T”-shaped connector 250. An outlet of the “T”-shaped connector 250 is fluidly connected to the gas distribution device 211. The gas sources can supply a single gas, a mixture of a carrier gas and an entrained vapor, a mixture of two or more gases, etc. In some examples, the gas flow channels and/or gas conduits have a circular cross-section, although other cross-sections may be used.

In some examples, the gas source 214 supplies an inert gas or a carrier gas such as argon (Ar). The gas source 218 supplies a purge gas such as molecular nitrogen (N₂). The gas source 244 supplies a first precursor. The gas source 222 supplies a second precursor such as an oxidizer.

Referring now to FIG. 2, a method 258 for performing atomic layer deposition is shown. At 260 the substrate 213 is exposed to a first precursor from the gas source 244 (and the carrier gas from the gas source 214) for a first predetermined period. After exposure to the first precursor, the processing chamber 210 is purged at 264 using the purge gas from the gas source 218 for a second predetermined period. After the second predetermined period, the substrate 213 is exposed to the second precursor (e.g., oxidizer) from the gas source 222 for a third predetermined period at 268. After the third predetermined period, the processing chamber 210 is purged at 270. The process can be repeated one or more times.

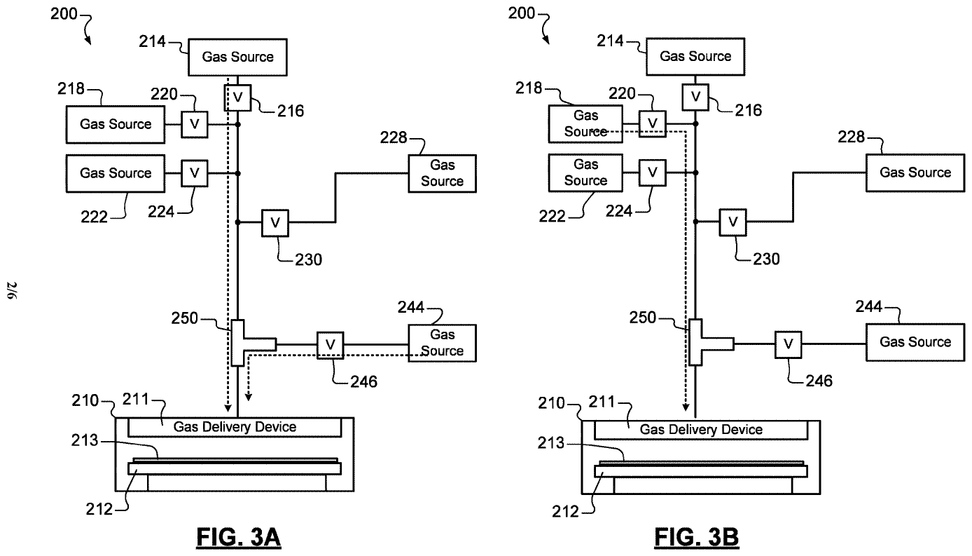

Referring now to FIGS. 3A to 3C, gas flow during the ALD process is shown. In FIG. 3A, dosing with the first precursor is shown during which the carrier gas from the gas source 214 and the first precursor from the gas source 244 are supplied to the “T”-shaped connector 250, the gas distribution device 211, and the processing chamber 210. In FIG. 3B, the purge step is shown during which the purge gas from the gas source 218 is supplied to the “T”-shaped connector 250, the gas distribution device 211, and the processing chamber 210. In FIG. 3C, dosing with the second precursor is shown during which gas from the gas source 222 is supplied to the “T”-shaped connector 250, the gas distribution device and the processing chamber 210.

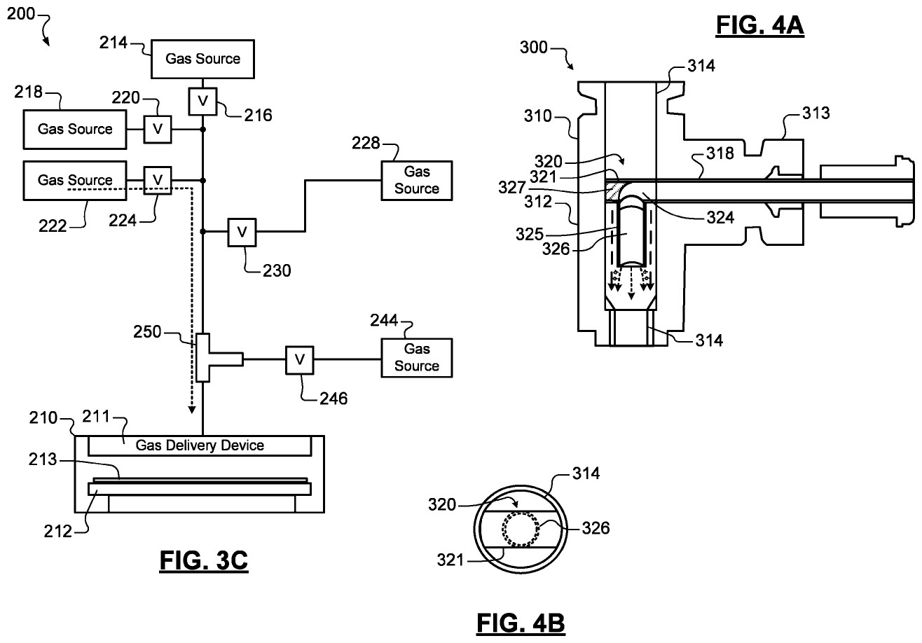

Referring now to FIGS. 4A and 4B, a “T”-shaped connector 300 includes a body 310 including a first body portion 312 extending in a first direction and a second body portion 313 extending in a second direction transverse to the first direction. The first body portion 312 defines a first gas flow channel 314 extending in the first direction. The second body portion 313 defines a second gas flow channel 318 extending in the second direction and intersecting with the first gas flow channel 314.

A “T”-shaped conduit 320 is arranged in the first gas flow channel 314 and includes a first conduit portion 321 extending in the second direction and defining a third gas flow channel 324 in fluid communication with the second gas flow channel 318. The “T”-shaped conduit 320 includes a second conduit portion 325 extending in the first direction and defining a fourth gas flow channel 326. In some examples, a plug 327 defining an arcuate surface 329 is arranged in the third gas flow channel 324 downstream from the connection to the second conduit portion 325. The arcuate surface 329 of the plug 327 redirects gas flowing in the second direction to gas flowing in the first direction towards the outlet.

The “T”-shaped conduit 320 redirects gas flowing in the third gas flow channel 324 in the second direction into the fourth gas flow channel 326 extending in the first direction. Gas flowing in the first gas flow channel 314 flows around the “T”-shaped conduit 320. Gas flowing in the second gas flow channel 318 is directed by the third gas flow channel 324 of the “T”-shaped conduit 320 into the fourth gas flow channel 326 extending in the first direction.

Gas exiting the fourth gas flow channel 326 is mixed with gas flowing in the first gas flow channel 314. In some examples, the gas flowing in the first gas flow channel 314 is flowing slower than the gas flowing in the fourth gas flow channel 326. The difference in velocity of the gases flowing in the first gas flow channel 314 and gases the fourth gas flow channel 326 causes mixing to occur.

In FIG. 4B, an inner diameter of the first gas flow channel 314 of the “T”-shaped connector 300 has a larger diameter an outer diameter of the first conduit portion 321 and the second conduit portion 325. This arrangement allow gas flowing in the first gas flow channel 314 to flow around the “T”-shaped conduit 320 without significant backpressure. In some examples, the inner diameter of the first gas flow channel is at least 1.5 times greater than an outer diameter of the first conduit portion 321 and/or the second conduit portion 325. In some examples, the inner diameter of the first gas flow channel is at least 2 times greater than an outer diameter of the first conduit portion 321 and/or the second conduit portion 325.

The “T”-shaped conduit 320 operates as a flow guide to deliver the precursor into the carrier gas stream during the dose step while avoiding stratification of the precursor. Improved mixing occurs downstream from the outlet of the “T”-shaped conduit 320 due to the Coanda effect. As a result, the “T”-shaped connector improves mixing and reduces substrate nonuniformity without causing backpressure and/or backflow associated with other approaches such as the helical mixer.

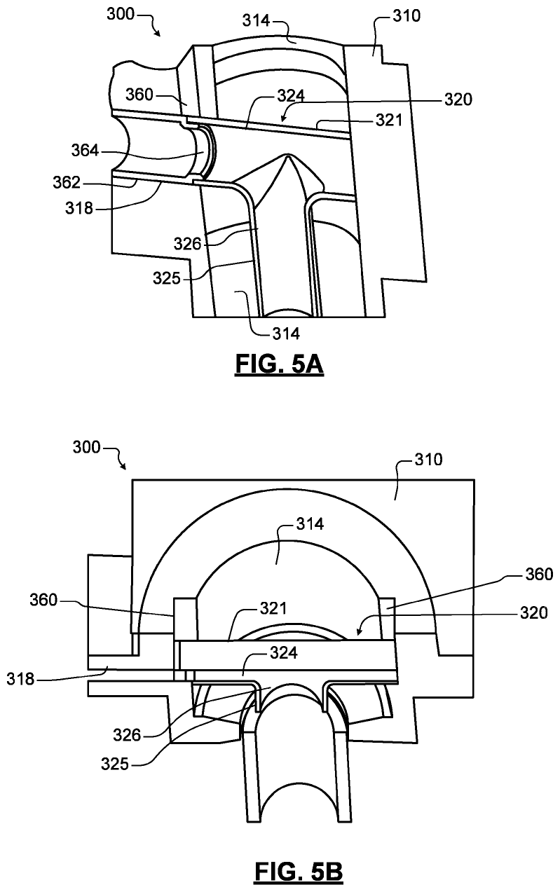

Referring now to FIGS. 5A and 5B, an example of the “T”-shaped conduit 320 and the “T”-shaped connector 300 are shown. In some examples, an inner diameter of the first gas flow channel 314 defines rectangular slots 360 to receive opposite ends of the first conduit portion of the “T”-shaped conduit 320. The second gas flow channel 318 is defined by a gas conduit 362 that includes an interlocking portion 364 to engage the “T”-shaped conduit 320. For example, the interlocking portion 364 may include a male projection that extends into the third gas flow channel 324 of the “T”-shaped conduit 320. In some examples, the “T”-shaped conduit 320 is inserted into the slots 360 with the gas conduit 362 arranged in a partially installed position. When the “T”-shaped conduit 320 is seated in the slots 360, the gas conduit 362 is moved laterally to engage the interlocking portion 364 with the inlet of the first conduit portion of the “T”-shaped conduit 320. While the conduit 362 includes a male projection, a female projection may also be used.

In some examples, the gas conduit 362 and the “T”-shaped conduit 320 are made of aluminum. In some examples, the body 310 is made of ceramic (e.g., alumina, zirconia, silicon nitride, silicon oxide, etc.).

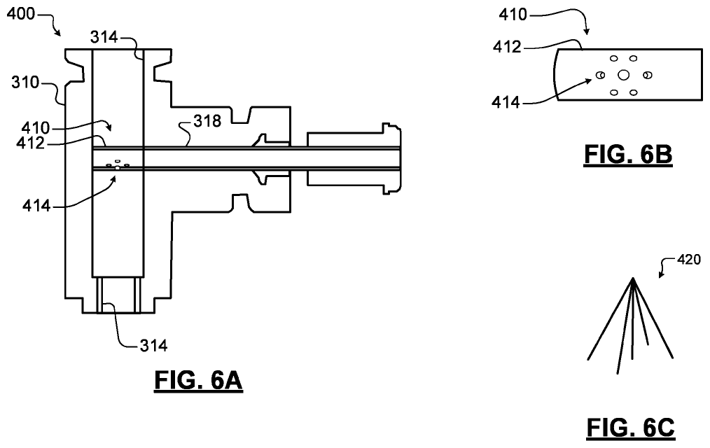

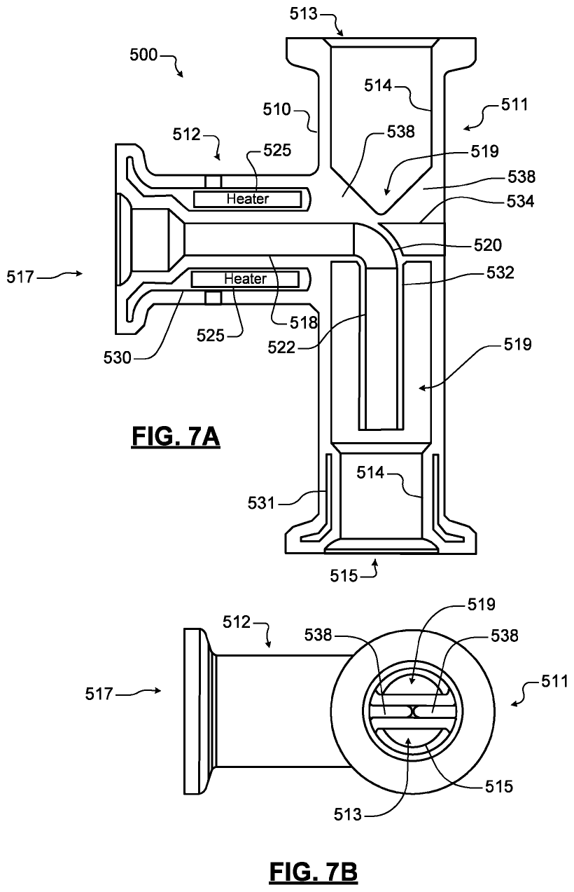

Referring now to FIGS. 6A to 6C, a “T”-shaped connector 400 is shown. In some examples, a gas conduit 410 is used instead of the “T”-shaped conduit 320. The gas conduit 410 extends linearly and defines a third gas flow channel 412 that receives gas from the second gas flow channel 318. The third gas flow channel 412 includes gas through holes 414 to supply gas from the third gas flow channel 412 downwardly in the first direction into the first gas flow channel 314 where mixing occurs.

In FIG. 6B, the gas through holes 414 may include a plurality of gas through holes. For example, one or more center gas through holes may be surrounded by a plurality of gas through holes arranged symmetrically or asymmetrically around the one or more center gas through holes. In some examples, the gas through holes extend in a radial direction relative to the gas conduit 410. In other examples, the gas through holes define a cone-shaped pattern 420 as shown in FIG. 6C. In other words, the one or more center gas through holes can be aligned with a radial direction and the other gas through holes surrounding the one or more center gas though holes are offset from the radial direction to define the cone-shaped gas flow pattern.

Referring now to FIG. 7A, a “T”-shaped connector 500 can be made using additive manufacturing such as 3D printing. The “T”-shaped connector 500 includes a body 510 including a first body portion 511 extending in a first direction and a second body portion 512 extending in a second direction transverse to the first direction. The first body portion 511 defines a first gas flow channel 514 extending in the first direction and including an inlet 513 and an outlet 515. The second body portion 512 defines a second gas flow channel 518 extending in the second direction and including an inlet 517.

A cantilevered body portion 519 extends from the second body portion 512 into the first gas flow channel 514. The cantilevered body portion 519 includes an angled body portion 520 and a third body portion 522. The cantilevered body portion 519 extends in the second direction into the first gas flow channel 514, turns at the angled body portion 520, and the third body portion 522 extends in the first direction in the first gas flow channel 514. The third body portion 522 extends partially towards the outlet 515 of the first body portion 511. In some examples, the cantilevered body portion 519 includes triangular reinforcing members 538 that extend between side walls of the first gas flow channel 514 and the cantilevered body portion 519.

In FIG. 7B, gas flowing into the inlet 513 of the first gas flow channel 514 flows in the first direction around the cantilevered body portion 519 to the outlet 515. Gas flowing in the second direction into the second gas flow channel 518 flows through the angled body portion 520 into the third body portion 522 and then exits the cantilevered body portion 519 and mixes with the gas in the first gas channel. In some examples, the angled body portion 520 turns or bends 90°.

In some examples, the “T”-shaped connector 500 is made of ceramic. In some examples, the “T”-shaped connector 500 includes cavities 530 and 531 that are defined during additive manufacturing. In some examples, the cavity is defined around the second gas flow channel 518 and the cavity 531 is defined near the outlet 515. In some examples, the cavities 530 and/or 531 are annular-shaped. In some examples, a heater 525 is arranged in the cavity 530 to heat gases flowing in the second gas flow channel 518. In some examples, the heater 525 comprises a resistive heater.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

What is claimed is:

1. A connector for a substrate processing system comprising:
a body comprising:
a first body portion including an inlet and an outlet and defining a first gas flow channel extending in a first direction from the inlet to the outlet; and
a second body portion including an inlet and defining a second gas flow channel extending in a second direction that is different than the first direction; and
a “T”-shaped conduit arranged in the first gas flow channel and including:
a first conduit portion defining a third gas flow channel extending in the second direction and including an inlet connected to the second gas flow channel; and
a second conduit portion connected to a downstream side of the first body portion and defining a fourth gas flow channel extending in the first direction and in fluid communication with the third gas flow channel.

2. The connector of claim 1, wherein the first body portion includes a first slot and a second slot located on an inner surface of the first gas flow channel, wherein opposite sides of the first conduit portion are received in the first slot and the second slot.

3. The connector of claim 2, wherein the second body portion comprises an interlocking portion configured to engage the inlet of the first conduit portion.

4. The connector of claim 3, wherein the interlocking portion of the second body portion comprises a gas conduit including a male projection received in the inlet of the first conduit portion.

5. The connector of claim 1, further comprising a plug arranged in the third gas flow channel downstream from a connection to the fourth gas flow channel and including an arcuate surface configured to redirect gas flowing in the third gas flow channel into the fourth gas flow channel.

6. The connector of claim 1, wherein an inner diameter of the first gas flow channel is greater than an outer diameter of the first conduit portion and the second conduit portion.

7. The connector of claim 1, wherein an inner diameter of the first gas flow channel is at least 1.5 times greater than an outer diameter of the first conduit portion and the second conduit portion.

8. The connector of claim 1, wherein the first direction is transverse to the second direction.

9. A connector for a substrate processing system comprising:
a body comprising:
a first body portion including an inlet and an outlet and defining a first gas flow channel extending in a first direction between the inlet and the outlet; and
a second body portion including an inlet and defining a second gas flow channel extending in a second direction that is different than the first direction; and
a gas conduit arranged in the first gas flow channel and defining a third gas flow channel extending in the second direction, including an inlet connected to the second gas flow channel, and including a plurality of gas through holes passing through the gas conduit on a downstream side of the gas conduit.

10. The connector of claim 9, wherein the first body portion includes a first slot and a second slot located in the first gas flow channel and configured to receive opposite sides of the gas conduit.

11. The connector of claim 10, wherein the second body portion comprises an interlocking portion configured to engage the inlet of the gas conduit.

12. The connector of claim 11, wherein the interlocking portion of the second body portion comprises a gas conduit including a male projection received in the inlet of the gas conduit.

13. The connector of claim 9, further comprising a plug arranged in gas conduit downstream from the plurality of gas through holes.

14. The connector of claim 9, wherein an inner diameter of the first gas flow channel is greater than an outer diameter of the gas conduit.

15. The connector of claim 9, wherein an inner diameter of the first gas flow channel is at least 1.5 times greater than an outer diameter of the gas conduit.

16. The connector of claim 9, wherein the plurality of gas through holes are configured to provide a conical gas flow pattern.

17. The connector of claim 9, wherein the first direction is transverse to the second direction.

18. A connector for a substrate processing system comprising:
a body comprising:
a first body portion including an inlet and an outlet and defining a first gas flow channel extending in a first direction from the inlet to the outlet; and
a second body portion including an inlet and an outlet and defining a second gas flow channel extending in a second direction that is different than the first direction; and
a cantilevered body portion extending from the second body portion into the first gas flow channel and including:
an angled body portion extending from the second body portion into the first gas flow channel; and
a third body portion extending from the angled body portion in the first gas flow channel,
wherein the second gas flow channel extends through the second body portion, the angled body portion and the first body portion, and
wherein gas flowing through the first gas flow channel is combined with gas flowing through the second gas flow channel at the outlet of the third body portion.

19. The connector of claim 18, wherein the connector is made using additive manufacturing.

20. The connector of claim 18, wherein an inner diameter of the first gas flow channel is greater than an outer diameter of the angled body portion and the third body portion of the cantilevered body portion.

21. The connector of claim 18, wherein an inner diameter of the first gas flow channel is greater than 1.5 times an outer diameter of the angled body portion and the third body portion of the cantilevered body portion.

22. The connector of claim 18, wherein the first direction is transverse to the second direction.

23. The connector of claim 18, further comprising a cavity defined in the second body portion around the second gas flow channel.

24. The connector of claim 23, further comprising a heater arranged in the cavity.
